(19) United States
(12) Patent Application Publication
(10) Pub. No.: US 2006/0094219 A1
(43) Pub. Date: May 4, 2006

(54) Method for manufacturing electronic device

(75) Inventor: Eiichi Soda, Tsukuba (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/255,979

(22) Filed: Oct. 24, 2005

(30) Foreign Application Priority Data
Nov. 1, 2004 (JP) 2004-317718

(51) Int. Cl. H01L 21/44

(52) U.S. Cl. 438/597

(57) ABSTRACT

The method for manufacturing an electronic device is provided. The method includes: applying an active hydrogen species over a surface of an underlying interconnect formed on a substrate and having an anti-corrosion material formed on the surface thereof and containing copper, to remove the anti-corrosion material; and forming an insulating barrier layer, which functions as a copper diffusion barrier film, on the underlying interconnect via a chemical vapor deposition or an atomic layer deposition employing a reactive gas of a mixture of an organosilane gas and an active nitrogen species. The active hydrogen species is generated from hydrogen gas or a gaseous mixture of hydrogen gas and inert gas, and the active nitrogen species is generated from nitrogen gas or a gaseous mixture of nitrogen gas and inert gas, and the active hydrogen species and the active nitrogen species are separately generated and used, respectively.

This application is based on Japanese Patent Application NO. 2004-317,718, the content of which is incorporated hereinto by reference.

### BACKGROUND

1. Technical Field

The present invention relates to a method for manufacturing an electronic device.

2. Related Art

In recent years, remarkably increasing processing speed of the semiconductor device leads to a problem of generating a transmission delay due to a decrease in a signal propagation rate, which is caused by an interconnect resistance in a multi-layer interconnect and a parasitic capacitance between the interconnects. Such problem tends to become more and more considerable, due to an increased interconnect resistance and an increased parasitic capacitance, which are caused in accordance with miniaturizations of a line width and an interconnect interval created by an increased integration of the semiconductor device. Consequently, in order to prevent a signal delay caused on the basis of enhancements in the interconnect resistance and in the parasitic capacitance, it has been attempted that a copper interconnect is introduced as a substitute for a conventional aluminum interconnect, and a low dielectric constant film (hereinafter referred to as “low-k film”) is employed for an interlayer insulation film. Here, the low dielectric constant film may be an insulating film having a relative dielectric constant less than a relative dielectric constant of a silicon dioxide (SiO₂) film of 3.9.

A damascene process is a process for forming the above-described copper interconnect. This is a technology of forming the interconnects without etching Cu, in view of the fact that control of the etch rate for copper (Cu) is difficult as compared with aluminum (Al), or more specifically, this is a damascene interconnect (trench interconnect) technology, in which trenches for interconnects (trenches) or connection apertures (via holes) are formed in an insulating interlayer via a dry etching process and then such trenches or via holes are filled with Cu or Cu alloy.

In so-called dual damascene interconnect technology, in which trenches (trenches for dual damascene interconnects) formed by connecting the above-described trench with the via holes are provided in the above-described insulating interlayer and then the trenches and via holes are integrally plugged with an interconnect material film, various types of formation methods are energetically developed toward the practical use thereof. The formation methods of the dual damascene interconnect can be roughly classified into a via first method, a trench first method and a dual hard masking method, depending on differences in the method for forming trench for the above-described dual damascene interconnect. In these methods, the via first method and the trench first method involve forming trenches for dual damascene interconnects via a dry etching process of the insulating interlayer employing a resist mask. The via first method further involves first forming via holes, and then forming trenches, and the trench first method further involves, inversely, first forming trenches, and then forming via holes. On the contrary, the above-described dual hard masking method involves collectively forming the trenches for dual damascene interconnects via a dry etching process of the insulating interlayer employing a hard mask.

Amongst the above-described dual damascene interconnect technologies, the above-described via first method has the following benefits, as compared with other methods. That is, compatibility thereof with the single damascene process is higher and thus a conversion thereto is easier in the photolithography process and the dry etching process, and a reduction of leakage current between the damascene interconnects is facilitated. Accordingly, investigations concerning the above-described via first method toward the practical use are widely carried out in recent days (see, for example, Japanese Patent Laid-Open No. 2004-221,439).

However, the formation process for the dual damascene interconnect employing the above-described via first method may cause a problem, in which so-called resist poisoning phenomenon is typically generated on the resist mask that is employed for forming the trenches for interconnects. Therefore, a problem of difficulties in forming the trench openings of the resist mask with higher minuteness and precision is arisen.

### SUMMARY OF THE INVENTION

According to one aspect of the present invention, there is provided a method for manufacturing an electronic device. The method includes: applying an active hydrogen species over a surface of an underlying interconnect to remove an anti-corrosion material, the underlying interconnect being formed on a substrate, having the anti-corrosion material formed on the surface thereof and containing copper; forming an insulating barrier layer on the underlying interconnect via a chemical vapor deposition or an atomic layer deposition employing a reactive gas of a mixture of an organosilane gas and an active nitrogen species, the insulating barrier layer functioning as a copper diffusion barrier film; forming an insulating interlayer on the insulating barrier layer, the insulating interlayer being a different type from the insulating barrier layer; forming a first resist mask on the insulating interlayer, the first resist mask having an opening for forming a concave portion in the insulating interlayer; etching the insulating interlayer via a dry etching process by employing the first resist mask as an etching mask to form the concave portion; and plugging an electric conductor film in the concave portion. In the method, the active hydrogen species is generated from hydrogen gas or a gaseous mixture of hydrogen gas and inert gas, and the active nitrogen species is generated from nitrogen gas or a gaseous mixture of nitrogen gas and inert gas. The active hydrogen species and the active nitrogen species are separately generated and used, respectively.

Here, the insulating interlayer may be a low dielectric constant film. In these operations, it may be designed that the active hydrogen species and the active nitrogen species are not simultaneously employed. Further, in these operations, it may be designed that ammonia gas (ammonia plasma) is not employed. The method for manufacturing the electronic device according to the present invention may be applied to the dual damascene interconnect that includes the trenches for via holes and the interconnects, which are integrally provided in the insulating interlayer. Amongst these, in particular, the present invention can be applied to the via first method that involves first forming the via holes.

The method may further include, between the forming the insulating interlayer and the forming the first resist mask: forming a via hole extending to the insulating barrier layer in the insulating interlayer; and depositing a resin film that plugs the via hole to form a dummy plug composed of the resin film in the via hole. In this method, in the forming the first resist mask, the first resist mask may be formed such that the opening defines the concave portion as a trench for the interconnect formed on the dummy plug and on the insulating interlayer. Further in this method, in the forming the concave portion, the trench for the interconnect connected to the via hole may be formed. Further in this method, in the plugging the electric conductor film in the concave portion, the electric conductor film may plug the via hole and the trench for the interconnect to form a dual damascene interconnect.

Such configuration according to the present invention provides an inhibition to the resist poisoning in the formation of the resist mask having the interconnect-patterned trench opening, and also provides a formation of the trench for dual damascene interconnect having fine structure and better quality and the dual damascene interconnect formed by plugging thereof with an interconnect material film under higher controllability, thereby considerably improving a production yield of the electronic device comprising the dual damascene interconnects.

According to the configuration of the present invention, the resist poisoning can be inhibited in the formation of the resist mask having certain openings to provide a production of the electronic device having fine structure and better quality.

### BRIEF DESCRIPTION OF THE DRAWINGS

The above and other objects, advantages and features of the present invention will be more apparent from the following description taken in conjunction with the accompanying drawings, in which:

FIGS. 1A to 1C are cross sectional views of a semiconductor device, illustrating a preferable formation process for a dual damascene interconnect according to an embodiment of the present invention;

FIG. 2 is a sectional view explaining an effect by the embodiment of the present invention;

FIG. 3 is a sectional view explaining an effect by the embodiment of the present invention;

FIG. 4 is a sectional view explaining an effect by the embodiment of the present invention;

FIG. 5 is a cross sectional view of a semiconductor device, illustrating a preferable operation for forming a dual damascene interconnect according to an embodiment of the present invention;

FIGS. 6A to 6C are cross sectional views of a semiconductor device, illustrating the formation process for a dual damascene interconnect according to an embodiment of the present invention;

FIGS. 7A to 7C are cross sectional views of a semiconductor device, illustrating the formation process for a dual damascene interconnect according to an embodiment of the present invention, which is continued after the process shown in FIGS. 6A to 6C;

FIGS. 8A to 8C are cross sectional views of a semiconductor device, illustrating the formation process for a dual damascene interconnect according to an embodiment of the present invention, which is continued after the process shown in FIGS. 7A to 7C; and

FIGS. 9A and 9B are cross sectional views of a semiconductor device, illustrating the resist poisoning phenomenon.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferred embodiments of the present invention will be described as follows in reference to the annexed figures.

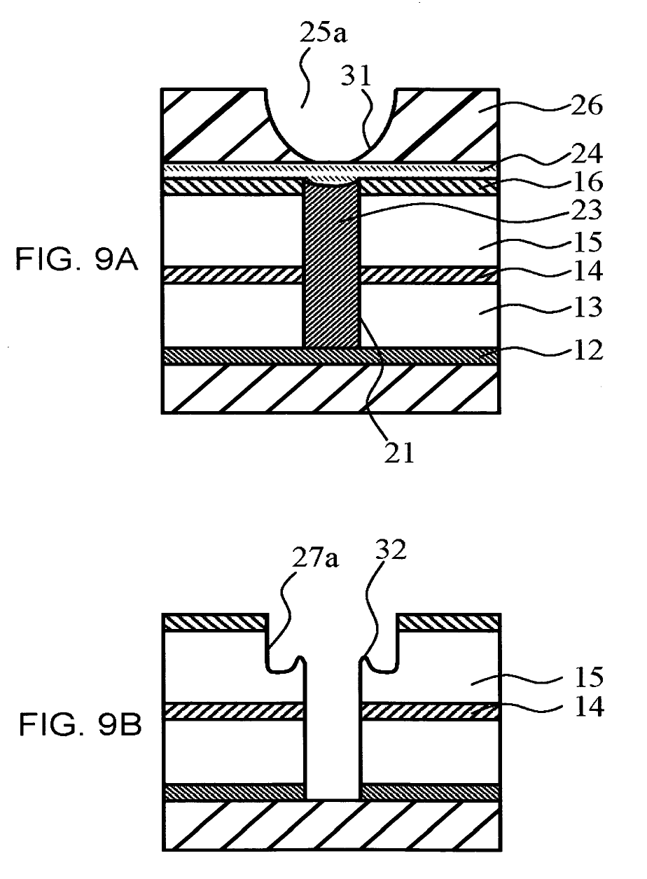

The present inventor had studied the resist poisoning phenomenon. The phenomenon will be described as follows in reference to FIGS. 9A and 9B.

When a photo resist for ArF excimer laser exposure, for example, is irradiated with light and then developed, in order to form the second resist mask 26 using a chemically amplified positive resist in the photolithography process, the resist in the region around the trench opening 25 is not fully dissolved, resulting in a developing failure and a generation of a remaining resist (scum) 31 on the bottom of the trench opening 25a, as shown in FIG. 9A. Thus, fine and highly precise formation of the trench opening into an interconnect pattern becomes difficult.

When a second anti-reflection coating 24, a cap layer 16 and a second low dielectric constant film 15 are dry etched through a mask of the second resist mask 26 that contains such scum 31 generated thereon, an insufficient trench 27a that does not extend to a surface of a trench etch stop layer 14 is formed in the second low dielectric constant film 15, as shown in FIG. 9B. In addition, a crown-shaped fence 32 is easily formed along the circumference of the via hole. Because of these reasons, it is difficult to form the trenches for dual damascene interconnects having fine structure and better quality and the dual damascene interconnect formed by plugging thereof with the interconnect material film.

It is considered that the above-described resist poisoning phenomenon is caused because a basic substance of an alkaline component promotes a deactivation of an acid generation agent contained in a chemically amplified resist in a coating operation, a pre-baking operation, an exposure operation or a post exposure baking (PEB) operation for the chemically amplified positive (or negative) resist in the photolithography process.

The present inventor have involved detailed investigations for respective operations in the process for forming of the dual damascene interconnects, and found that ammonia (NH₃) gas or hydrazine (N₂H₄) gas used in the above-described formation process has a considerable role in creating the above-described resist poisoning phenomenon. In particular, the present inventor have found that a basic substance diffusing through a dummy plug 23 plugged within the via hole 21 provided in the insulating interlayer, which includes a first low dielectric constant film 13, the trench etch stop layer 14, the second low dielectric constant film 15 and the cap layer 16, as shown in FIG. 9A, promotes a deactivation of an acid generation agent contained in a chemically amplified resist. The present invention is made based on the scientific knowledge.

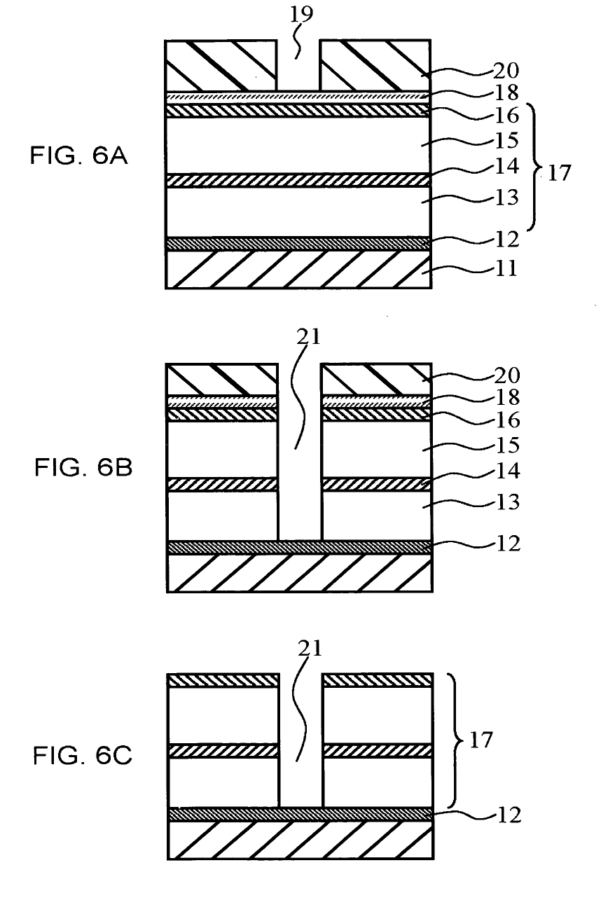

Hereinafter, a procedure for manufacturing an electronic device by the via first method will be described in reference to FIGS. 6A to 6C, FIGS. 7A to 7C and FIGS. 8A to 8C. FIGS. 6A to 6C, FIGS. 7A to 7C and FIGS. 8A to 8C are cross-sectional views of the device for describing respective operations for manufacturing the electronic device.

Here, a substrate may be a semiconductor substrate such as silicon substrate on which elements such as transistors are formed and the like.

As shown in FIG. 6A, a via etch stop layer 12 is formed on an underlying interconnect 11. The underlying interconnect 11 may be consisting of a copper interconnect. The via etch stop layer 12 functions as an insulating barrier layer that can be a Cu diffusion barrier film. The via etch stop layer 12 may be composed of, for example, silicon carbonitride (SiCN) film or silicon carbide (SiC) film. The film thickness of the via etch stop layer 12 may be about 25 nm.

Then, a first low dielectric constant film 13, a trench etch stop layer 14, a second low dielectric constant film 15 and a cap layer 16, each of which has an appropriate film thickness, are formed in this order on the via etch stop layer 12 to provide a multi-layer structure.

Here, the first low dielectric constant film 13 and the second low dielectric constant film 15 may be composed of low-k films having relative dielectric constants of equal to or less than 3. The low-k film may be, for example, a carbon-containing silicon oxide film (SiOC film), a methyl silsesquioxane (MSQ) film, or the like. The SiOC film can be formed by a chemical vapor deposition (CVD). The MSQ film may be formed by employing a coating process. The MSQ film may have a film formulation of, for example, [CH₃SiO_{3/2}]n.

Alternatively, The low-k film may be a porous film such as a porous MSQ film (p-MSQ film). By employing the porous film, the relative dielectric constant thereof can be reduced to a value of equal to or less than 2.5.

The trench etch stop layer 14 may be, at least, an insulating film of a different type from the second low dielectric constant film 15 or from the via etch stop layer 12. The trench etch stop layer 14 may be, for example, SiC film, SiCN film, SiOC film or silicon nitride (SiN) film or the like.

In addition, the cap layer 16 may be formed with an SiO₂ film. In another case, the electrical device may not include the cap layer 16.

As described above, the insulating interlayer 17 having the multiple-layered insulating film structure composed of the via etch stop layer 12, the first low dielectric constant film 13, the trench etch stop layer 14, the second low dielectric constant film 15 and the cap layer 16 is formed.

Next, a first anti-reflection film 18 is formed on the surface of the cap layer 16. Then, a first resist mask 20 having a via opening 19 is formed on the first anti-reflection film 18 via a photolithographic technology. Subsequently, as shown in FIG. 6B, the first anti-reflection film 18, the cap layer 16, the second low dielectric constant film 15, the trench etch stop layer 14 and the first low dielectric constant film 13 are sequentially dry etched via a reactive ion etching (RIE) employing the first resist mask 20 as a mask for the dry etching process to provide a bore through the multiple-layered insulating film, thereby forming a via hole 21 extending to the surface of the via etch stop layer 12. At this time, the via etch stop layer 12 is not etched.

Next, as shown in FIG. 6C, the first resist mask 20 and the first anti-reflection film 18 are removed via an ashing process and then are cleaned with a chemical solution to form the via hole 21 extending to the surface of the via etch stop layer 12 of the insulating interlayer 17.

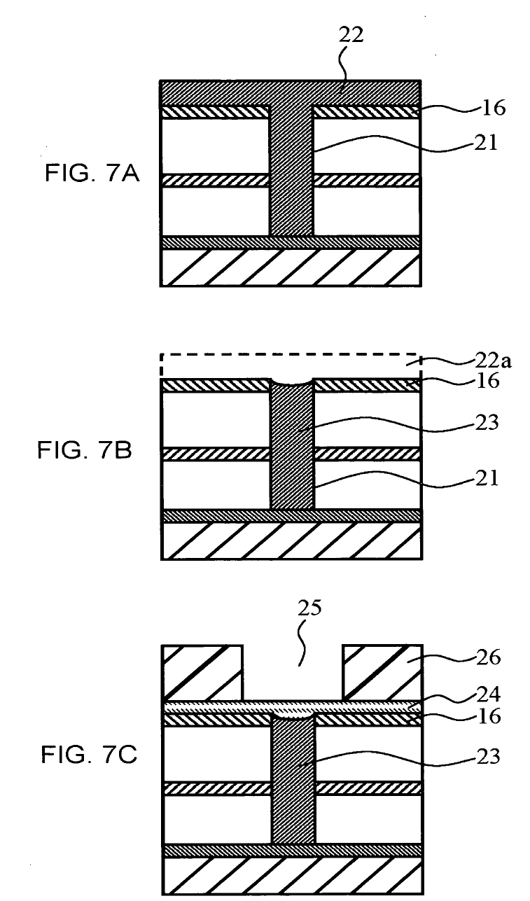

Then, as shown in FIG. 7A, a resin film 22 is applied and formed on the cap layer 16 via a spin coating process so as to fill the via holes 21 therewith, and then the applied resin film 22 are cured by thermally processing thereof at a temperature of about 100 to 225 degree C. Here, an organic polymer having thermosetting nature and being composed of various types of compositions, such as for example, novolak type phenolic resin, is employed for the resin film 22.

Then, as shown in FIG. 7B, the resin film 22a disposed on the surface of the cap layer 16 is removed via an etchback process to form a dummy plug 23 so as to plug the via hole 21 therewith. In the meantime, when the above-described resin film 22 has a function as the anti-reflection film, the etchback operation illustrated in FIG. 7B may be omitted, leaving the resin film 22 (as illustrated by dotted line 22a) on the cap layer 16.

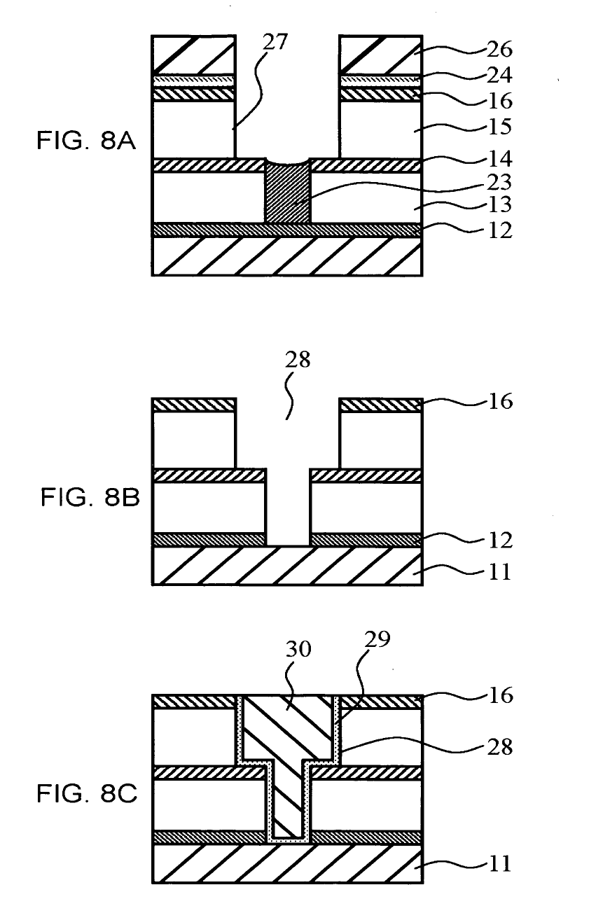

Next, as shown in FIG. 7C, a second anti-reflection film 24 and a second resist mask 26 having a trench opening 25 are formed via a photolithographic technology so as to coat the surface of the cap layer 16 and the dummy plug 23. Then, as shown in FIG. 8A, the second anti-reflection film 24, the cap layer 16 and the second low dielectric constant film 15 are sequentially dry etched via a RIE employing the second resist mask 26 as a mask for the dry etching process. In such case, the dummy plug 23 provides a protection to the via etch stop layer 12 from the influence of the above-described RIE process, and the first trench etch stop layer 14 provides a protection to the low dielectric constant film 13 from the influence of the above-described RIE process. In this way, an interconnect-patterned trench 27 is formed.

Next, the second resist mask 26, the second anti-reflection film 24 and the dummy plug 23 are removed via an ashing process, and then, the via etch stop layer 12 is dry etched by utilizing plasma excitation employing a fluorocarbon type gas as a gas for etching in the dry etching process utilizing the cap layer 16 as a hard mask, thereby forming a trench 28 for the dual damascene interconnect that extends to the surface of the underlying interconnect 11. Then, the exposed surface of the underlying interconnect 11 is cleaned with an oxidization-free chemical solution to remove residues therefrom.

Next, as shown in FIG. 8C, a deposition of a barrier metal such as tantalum nitride (TaN) and the like via a sputtering or an atomic layer deposition (ALD) is conducted. Then, a formation of a Cu seed, and a metal plating of Cu are conducted to form an interconnect material film. And then, an unwanted portion of the interconnect material film on the surface of the cap layer 16 is polished to be removed via a chemical mechanical polishing (CMP). In this way, an electrical conductive barrier layer 29, which is connected to the underlying interconnect 11 and functions as a Cu diffusion barrier film, and a dual damascene interconnect 30, which is wrapped by the barrier layer 29, are formed in the trench 28 for the above-described dual damascene interconnect.

The resist poisoning phenomenon is likely to occur in the process for forming the second resist mask 26. The reason for this is considered that a source gas (gas for etching) containing oxygen (O₂) gas, ammonia (NH₃) or hydrazine (N₂H₄) of plasma-excited is employed as an etch gas for conducting a dry etching process shown in FIG. 7B, for example.

Main operations suitable for forming the dual damascene interconnect described in reference to FIGS. 6A to 6C, FIGS. 7A to 7C and FIGS. 8A to 8C will be sorted out and be fully described as follows.

(Formation of Underlying Interconnect)

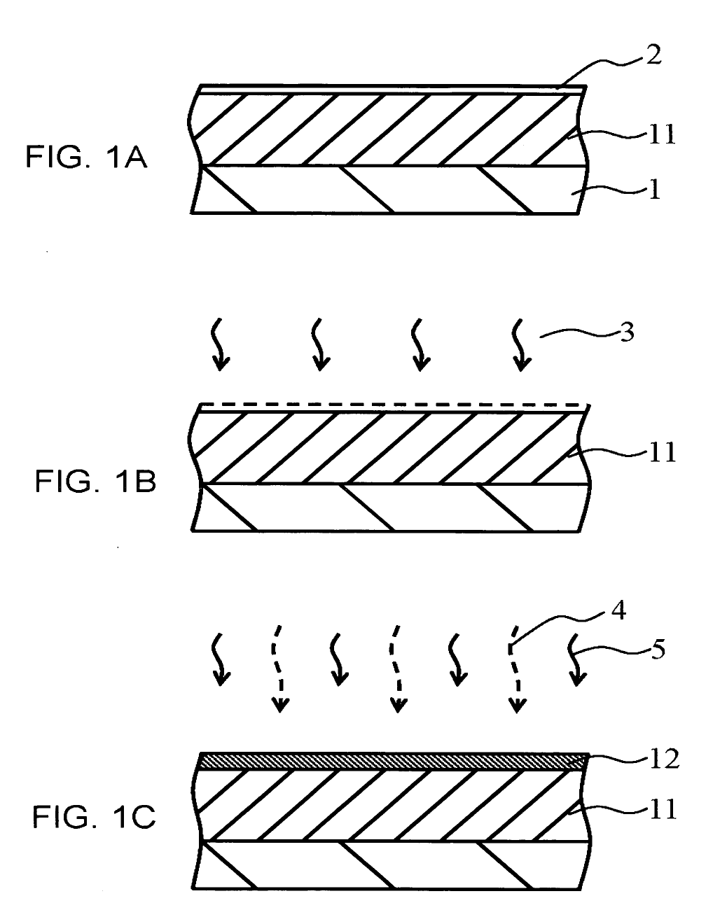

As shown in FIG. 1A, in a process for manufacturing a semiconductor device, which is an electronic device, an anti-corrosion material 2 is formed on a surface of an underlying interconnect 11. The underlying interconnect 11 may be composed of Cu. The underlying interconnect 11 may be formed on a base insulating film 1 via a damascene interconnect technology. Since Cu material is easily be oxidized and the oxidation of the surface of the underlying interconnect 11 by oxygen in air caused in the above-described manufacturing line should be prevented. By introducing the anti-corrosion material 2, the oxidation of the surface of the underlying interconnect 11 can be prevented. In this case, the anti-corrosion material 2 may be formed with an organic solvent of free of oxygen such as benzotriazole (BTA). The anti-corrosion material 2 may be formed by coating BTA, for example.

The underlying interconnect may be formed in a similar way as used in forming the dual damascene interconnect 30 stated above. A concave portion formed in the underlying layer insulating interlayer that has been formed on the substrate is plugged with an interconnect material including copper. Subsequently, the interconnect material exposed in the outside of the concave portion is removed via the CMP employing an acid slurry to form the underlying interconnect. In this occasion, an acid slurry such as, for example, T605-8 (commercially available from Hitachi Chemical Co., Ltd., Tokyo, Japan) is employed for the CMP polishing slurry. Subsequently, BTA is employed for an anti-corrosion material to form the anti-corrosion material on the surface of the underlying interconnect. Then, the surface of the underlying interconnect is cleaned with an acidic cleaning solution (for example, CMP-M05-203 (commercially available from Kanto Chemical)) and deionized water (DIW). In the above-described operation, it is preferable to employ an acidic solution or a neutral solution for the slurry cleaning solution or the cleaning solution, and is preferable to avoid employing an alkali solution, and in particular, to avoid employing an amine-containing solution. Here, the CMP and the surface treatment for the dual damascene interconnect 30 may also similarly conducted.

Subsequently, a process for removing the anti-corrosion material 2 is conducted as a pre-treatment for the next operation (formation of an insulating barrier layer).

In the present embodiment, as shown in FIG. 1B, the removal of the anti-corrosion material is conducted by applying a hydrogen-activated species 3 over the anti-corrosion material 2. Here, the hydrogen-activated species means hydrogen (H₂) in an excited state, and more specifically hydrogen atom ion (proton), hydrogen molecular ion or neutral hydrogen radical, and may be generated by exciting hydrogen gas or a gaseous mixture thereof with a noble (or inert) gas (He, Ar, Ne) via radio frequency (RF) plasma excitation, helicon wave plasma excitation, electron cyclotron resonance (ECR) plasma excitation, microwave plasma excitation, inductively coupled plasma (ICP) excitation or the like, or via photo-excitation. It is preferable to conduct the generation of hydrogen radical by employing so-called remote plasma generation apparatus for hydrogen gas or a microwave downstream type plasma apparatus.

The anti-corrosion material 2 on the surface of the above-described underlying interconnect 11 and the anti-corrosion material which has been coated on the surface of the base insulating film 1 without Cu-plugged are completely removed by applying active hydrogen species 3 comprising the above-described hydrogen plasma or hydrogen radical.

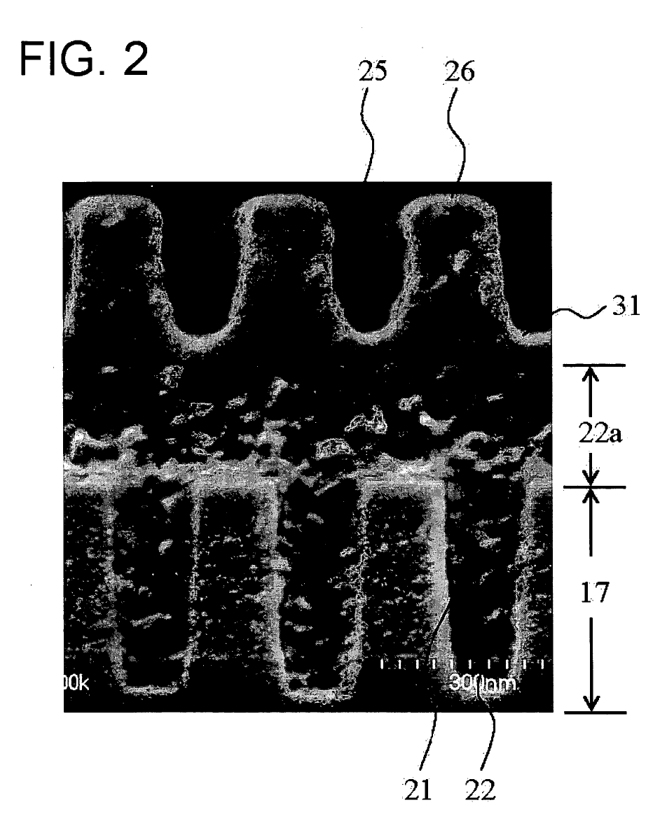

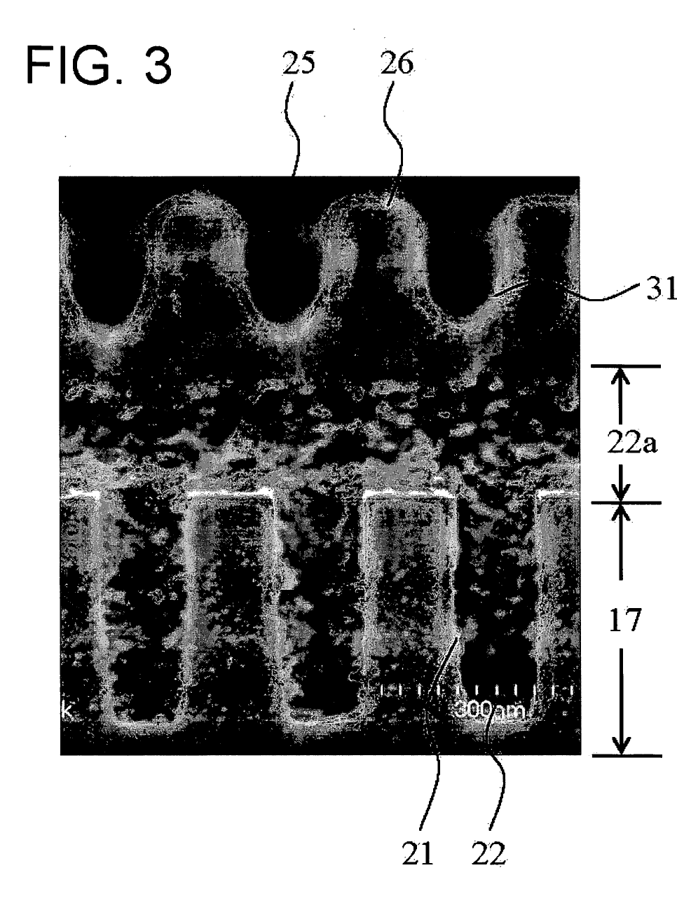

Advantageous effects obtainable by employing the above-described active hydrogen species for the removal of the anti-corrosion material will be described in reference to cross sectional views of scanning electron microscope (SEM) photographs shown in FIGS. 2 and 3. FIG. 2 shows a status of a case where the anti-corrosion material is removed by using a hydrogen plasma that is generated via a plasma excitation of a gaseous mixture H₂ and He with a microwave. In this process for removing the anti-corrosion material, the substrate temperature was set to 350 degree C., the gas pressure in the plasma chamber was set to 100 Pa, and the hydrogen concentration of the gaseous mixture was set to 5% vol. FIG. 3 shows a status of a reference example where the anti-corrosion material is removed by using an ammonia plasma that is generated via the above-described microwave plasma excitation of NH₃ gas. In the process for forming the structure shown in FIGS. 2 and 3, other operations for forming the structure were identical.

More specifically, in the operations described in reference to FIGS. 6A to 6C and FIGS. 7A to 7C, the via etch stop layer 12 was formed of an SiCN film, the first low dielectric constant film 13 and the second low dielectric constant film 15 were formed of “Aurora ULK” (trade name) that is a low dielectric constant film, the trench etch stop layer 14 was formed of an SiC film, and the cap layer 16 was formed of an SiO₂ film to provide the insulating interlayer 17, and then the via hole 21 was formed in the above-described insulating interlayer 17 except the via etch stop layer 12. Then, the resin film 22 having a function for working as the second anti-reflection film 24 was formed by coating, and the etchback operation and the formation of the second anti-reflection film 24 shown in FIG. 7B were omitted, and then the exposure and the developing for the chemically amplified positive resist were conducted under the same condition in the operation shown in FIG. 7C to form the second resist mask 26.

FIG. 2 and FIG. 3 show cross-sectional views after the operation of above-described FIG. 7C, and the same numeral is assigned to the same element. While the scum 31 is generated on the bottom of the trench opening 25 in both cases, larger amount of the scum 31 was generated in the case of FIG. 3 than the case of FIG. 2. According to the result, it can be seen that employing active hydrogen species is preferable for the removal of the anti-corrosion material 2 described in reference to FIG. 1 in view of inhibiting the resist poisoning than employing ammonia plasma.

(Formation of Insulating Barrier Layer)

After conducting the removal of the anti-corrosion material by applying the active hydrogen species in the process shown in the above-described FIG. 1B, the via etch stop layer 12 functioning as the insulating barrier layer for Cu is formed on the underlying interconnect 11, as shown in FIG. 1C. Here, the via etch stop layer 12 is formed of a SiCN film that is deposited as follows. The substrate temperature is set to around 300 degree C., and the via etch stop layer 12 composed of a SiCN film is deposited by applying an organosilane gas 4 such as, for example, hexamethyldisilane, ((CH₃)₆Si₂), tetraethyl silane ((C₂H₅)₄Si) and the like and an active nitrogen species 5 over the surface of the underlying interconnect 11, as shown in FIG. 1C. Here, the active nitrogen species means nitrogen ion, nitrogen molecular ion or neutral nitrogen radical. It is preferable to employ CVD or ALD employing the above-described reactive gas for depositing such SiCN film. In particular, a plasma enhanced atomic layer deposition (PEALD), in which nitrogen gas is plasma-excited while employing the above-described organosilane as a pre-cursor gas and the nitrogen plasma is applied thereto, is effective. The SiCN film deposited according to this method can provide a function of sufficient prevention for Cu diffusion even if the thickness thereof is equal to or less than 10 nm. Although the SiC film also functions as insulating barrier layer as stated above, the SiCN film provides better insulating ability, and thus is suitable. Here, the above-described active nitrogen species can be easily generated via a plasma excitation or a photo-excitation for nitrogen (N₂) or a gaseous mixture of the nitrogen and inert gas (or noble gas, such as He, Ar, Ne), similarly as in the case of generating the active hydrogen species stated above.

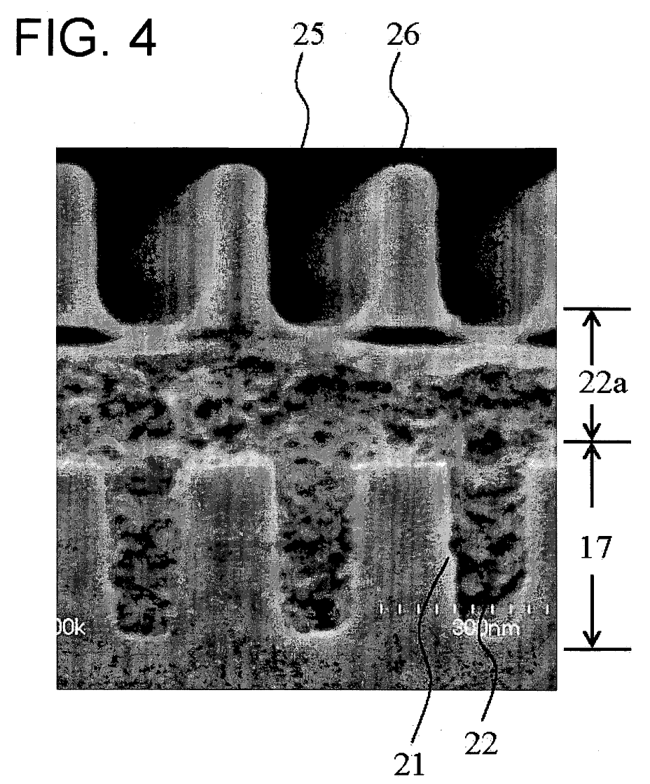

Advantageous effects obtainable by forming the above-described insulating barrier layer will be described in reference to FIGS. 2 to 4. Here, the deposition of the SiCN film for the insulating barrier layer shown in FIG. 2 and FIG. 3 were conducted via a CVD employing an organosilane and an ammonia plasma, which are commonly employed as a reactive gas, while the deposition of the SiCN film for the insulating barrier layer shown in FIG. 4 was conducted via a CVD employing an organosilane and the nitrogen plasma. The components included in the structure shown in FIG. 4, are similar to those described in FIG. 2 and FIG. 3, and thus the same numeral is referred to the same element therein and the detailed description thereof is not presented.

As shown in FIG. 4, almost no scum is generated on the bottom of the trench opening 25, and thus the difference in the generations of the scum 31 as compared with the examples shown in FIGS. 2 and 3 is quite evident. As such, it can be understood that the active nitrogen species is preferably employed as a reactive gas in the formation of the insulating barrier layer, as compared with a case of employing ammonia or the ammonia plasma, in view of providing an inhibition to the resist poisoning. In the comparison of the above-described cases shown in FIG. 2 and FIG. 3, smaller difference therebetween is appeared, since ammonia gas is commonly employed for depositing the above-described SiCN film in both cases.

The above-described SiCN film may also be applied to, for example, the trench etch barrier layer 14, as well as being applied to the etch stop layer 12 that functions as the insulating barrier layer. In such the case, the active nitrogen species may be similarly employed for the reactive gas for the deposition process, without employing ammonia or an ammonia plasma.

(Formation of Dummy Plug Composed of Resin Film)

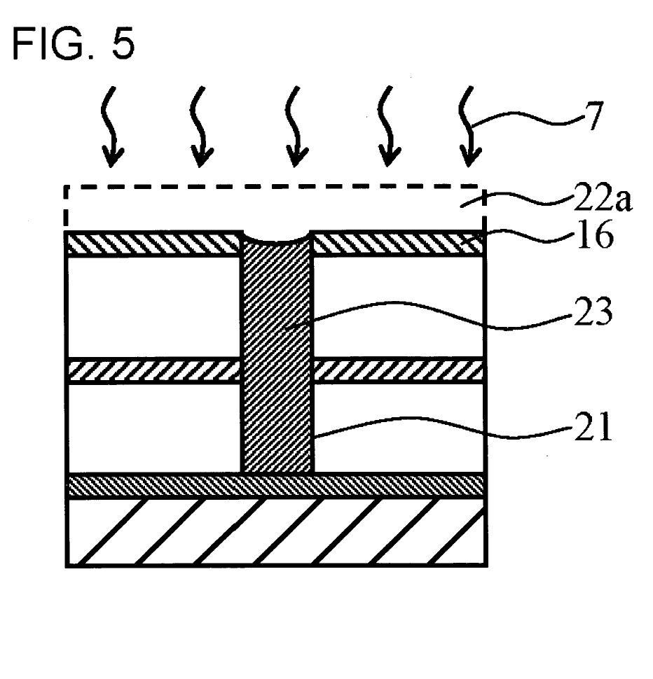

As shown in FIG. 5, it is preferable in the etchback operation for the resin film 22 shown in FIG. 7B that the active hydrogen species 7 is applied over the above-described resin film 22 to etch the resin film 22a on the cap layer 16 off from the cap layer to form the dummy plug 23 within the via hole 21. Here, the hydrogen-activated species may be generated by exciting hydrogen gas or a gaseous mixture thereof with a inert gas via radio frequency (RF) plasma excitation, helicon wave plasma excitation, electron cyclotron resonance (ECR) plasma excitation, microwave plasma excitation, inductively coupled plasma (ICP) excitation or the like, or via photo-excitation.

The above-described resist poisoning phenomenon that is occurred in the formation process for the second resist mask 26 can be inhibited by conducting an etchback process for the resin film 22 employing the active hydrogen species for the etchant gas. On the contrary, the above-described resist poisoning phenomenon is appeared by conducting an etchback process for the resin film 22 employing a plasma of a gaseous mixture of H₂ and N₂, or a plasma of ammonia gas or hydrazine gas for the etchant gas.

(Formation of Electrical Conductive Barrier Layer)

As shown in FIGS. 8A to 8C, an electrical conductive metal nitride such as TaN film is often employed for plugging the inside of the trench 28 for the dual damascene interconnect formed in the insulating interlayer 17 with Cu. When the TaN film is deposited via the sputtering process, a reactive sputtering process that involves introducing ammonia gas into a sputtering apparatus is usually employed. As for the embodiment of the present invention, nitrogen is introduced instead of ammonia in the above-described reactive sputtering process to form a nitrogen plasma. Further, when the deposition is conducted via the ALD process, usually, organic tantalum and ammonia are used as a pre cursor. As for the embodiment of the present invention, a nitrogen plasma or an active nitrogen species consisting of nitrogen radical, instead of ammonia, is used in the above-described ALD process. Metal nitride film such as WN film, WSiN film, TiN film, TiSiN film or the like may be employed for such electrical conductive barrier layer, in addition to the TaN film. In this case, the above-described nitrogen gas or the active nitrogen species may be employed as well. Having such procedure, a resist poisoning of the chemically amplified positive resist can be prevented, when the second level of the dual damascene interconnect is formed on the upper layer of the dual damascene interconnect 30 by employing the above-described via first method.

Besides, in the present embodiment, an active hydrogen species may be employed for the removal process of the first resist mask 20 and the second resist mask 26 via an ashing.

In addition, it is preferable to avoid using the resist-stripping solution containing an organic amine in the cleaning process with a chemical solution conducted after the above-described ashing.

As for an acidic pH controlling additive for the Cu slurry, for example, citric acid, phosphates or the like may be employed. Amongst these, citric acid is a preferable choice. In addition, as for an acidic pH controlling additives for the CMP cleaning solution, aliphatic polycarboxylic acids such as, for example, oxalic acid, malonic acid, tartaric acid, malic acid, citric acid or the like may be employed. Amongst these, oxalic acid is a preferable choice. As for an acidic pH controlling additives for the stripping and cleaning solution, organic acids such as, for example, formic acid, acetic acid, propionic acid, butanoic acid, isobutyric acid, oxalic acid, malonic acid, succinic acid, glutaric acid, maleic acid, fumaric acid, benzoic acid, phthalic acid, 1,2,3-benzene tricarboxylic acid, glycolic acid, lactic acid, malic acid, citric acid, salicylic acid or the like may be employed.

Further, it is preferable to avoid employing a gaseous mixture of H₂ and N₂, ammonia or hydrazine for the etchant gas utilized in the reactive ion etching (RIE), for example, in the dry etching process of the insulating interlayer 17 for forming the via hole 21.

In addition, for example in the deposition of SiN film, the active nitrogen species may be employed for the reactive gas utilized in the catalyst CVD or in the ALD, for example.

Further, as for the first low dielectric constant film 13 and the second low dielectric constant film 15 that are the low dielectric constant film, other insulating films having a siloxane backbone or an insulating film having a main backbone of an organic polymer, or a porous insulating film thereof may be employed by forming thereof with a known deposition process, in addition to the above-described SiOC film, methyl silsesquioxane (MSQ) film and “Aurora ULK” (trade name). The typical insulating film having the above-described siloxane backbone may be a silica film containing at least one of Si—CH₃ bond, Si—H bond, and Si—F bond, which is an insulating film of silsesquioxanes. The typical insulating film having the main backbone of the organic polymer may be “SiLK^{TR}” (trademark of the Dow Chemical Company) consisting of an organic polymer. Further, well known insulating materials for the insulating film of silsesquioxanes include hydrogen silsesquioxane (HSQ), methylated hydrogen silsesquioxane (MHSQ) or the like, and furthermore, SiOCH film deposited via a CVD may also similarly be employed.

Further, as for an etchant gas employed in the RIE of the insulating interlayer 17 for forming the via hole 21 in the operation shown in FIG. 6B, a fluorocarbon-containing gas of CF₄/Ar/N₂, for example, may be employed for etching the first anti-reflection film 18 via the dry etching process, the cap layer 16, the second low dielectric constant film 15, the trench etch stop layer 14, and the first low dielectric constant film 13. In addition to these, as for the above-described etchant gas, at least a source gas selected from the group consisting of fluorocarbon gases having a general formula of CxHyFz (where x, y, z are integer numbers that satisfy X≧1, Y≧0 and Z≧1) may be employed. Such fluorocarbon-containing gas may also be similarly employed for forming the trench 27 in the process shown in FIG. 8A.

In addition, in the dry etching process by using a hard mask of the cap layer 16 in the process shown in FIG. 8B, a gaseous mixture of CHF₃/Ar/N₂, a gaseous mixture of CF₄/Ar/N₂ or the like may be used for the etchant gas. Such etchant gas is plasma-excited to conduct a dry etching process for etching the via etch stop layer 12 to form the trench 28 for the dual damascene interconnect extending to the surface of the underlying interconnect 11.

In addition, as for the resin film 22, it is preferable to employ a thermosetting organic polymer that emit no basic substance or that is capable of trapping basic substance. As for the above-described resin film 22, for example, “NCA 2131” (trade name), commercially available from Nissan Chemical Industries, Co. Ltd., may be used.

In the above-described embodiment, in the process for forming the dual damascene interconnect, in stead of the reactive gas such as the gaseous mixture of hydrogen and nitrogen, ammonia, hydrazine and the like or the excited gas thereof, nitrogen gas and hydrogen gas may be separately employed, or alternatively the active hydrogen species and the active nitrogen species, which are separately formed by exciting nitrogen gas and hydrogen gas, respectively, via a plasma excitation or the like, may be separately employed. Having such procedure, in the process for forming the dual damascene interconnect employing the via first method, so-called resist poisoning of the chemically amplified positive resist, which is otherwise occurred in the formation of the second resist mask 26 having the trench opening 25, can be inhibited. Therefore, the trench opening 25 that is free of the scum, which is a resist remainder, can be stably formed with higher reproducibility.

It is considered that the deactivation of an acid generation agent contained in the chemically amplified positive resist in coating, pre-baking, exposing or post exposure bake (PEB) operations for the chemically amplified positive resist in the photolithographic operation in the process for forming the second resist mask 26 is occurred by using the gaseous mixture of hydrogen and nitrogen, ammonia gas, or hydrazine gas. By using these gases, the following phenomenon will occur. Firstly, the plasma excitation of the gaseous mixture of hydrogen and nitrogen, or the plasma excitation of ammonia gas, hydrazine gas or the gaseous mixture thereof promotes a generation of larger quantity basic materials such as NH, NH₂ and NH₃, and these basic materials or amines bounded to an alkyl group are incorporated as basic substances into the material film used for forming the above-described interconnect. Then, these basic substances upwardly diffuse mainly through the dummy plug 23. On the contrary, it is considered that, since the above-described embodiment according to the present invention has no operation of simultaneously plasma-exciting of hydrogen and nitrogen. Thus, the basic materials such as NH and NH₂ are not generated, in particular, and quantity of the generated basic substances is considerably reduced, thereby providing an inhibition to the resist poisoning phenomenon.

As such, according to the present embodiment, the problem of the resist poisoning is eliminated to facilitate further miniaturization in the dimension of the dual damascene interconnect, thereby promoting an increase in the processing speed of the semiconductor device. In addition, the embodiment presents a stable formation of the long and narrow trench 25 having an interconnect pattern, and thus higher process flexibility is provided to improve the manufacturing yield of the semiconductor device, thereby reducing the manufacturing cost of a semiconductor device having the dual damascene interconnect structural member.

According to the method of forming the dual damascene interconnect on the substrate by the via first method, fine and highly precise trench opening can be formed while the resist poisoning phenomenon, which is easily occurred in the process for forming the resist mask having the interconnect-patterned trench opening, is reduced. Therefore, it is possible to form the trench for the dual damascene interconnect having the fine structure and the improved quality.

While the preferable embodiment of the present invention has been described as described above, it is not intended to limit the scope of the present invention to the embodiment described. It is possible for a person having ordinary skills in the art to modify and/or change the specific embodiments in various ways without departing from the scope and the spirits of the present invention.

For example, the present invention may also be similarly applicable to a case of employing a chemically amplified negative resist in place of the chemically amplified positive resist, in the process for forming the resist mask having the trench opening.

In addition, the damascene interconnect having the above-described via hole or trench plugged with other type of the electric conductor film may also be formed, in stead of plugged with Cu or a Cu alloy. In this case, a refractory metal film such as a tungsten (W) film or a gold (Au) film may be employed for the electric conductor film.

In addition, while the case of employing the low-k film as the insulating interlayer between interconnects has been described in the above-described embodiment, it is not intended to limit the scope of the present invention to such insulating film, and the present invention may equally be applicable to cases where the insulating interlayer is formed with an insulating film such as a silicon oxide film, a silicon nitride film, a silicon oxynitride film and the like.

Further, it should be noted that the present invention is not particularly limited to the case where the dual damascene interconnect is formed on the semiconductor substrate such as the silicon semiconductor substrate, the compound semiconductor substrate and the like. Alternatively, the present invention may also equally be applicable to cases where the insulating interlayer is formed on a liquid crystal display substrate composing a display device or a plasma display substrate.

In addition, the present invention is not limited to be applicable to the via first method, and may also be applicable to various configurations for forming the via hole and the interconnect trench by employing a resist film, in particular employing a chemically amplified resist.

The present invention also includes the following configuration.

A method for manufacturing an electronic device, in which a via hole and a trench for an interconnect are integrally provided in an insulating interlayer formed on a substrate, and said via hole and said trench for the interconnect are plugged with an electric conductor film to form a dual damascene interconnect, said method includes a process for forming said dual damascene interconnect, comprising at least:

(a) forming an insulating barrier layer on the substrate, said insulating barrier layer functioning as Cu diffusion barrier film;

(b) forming a low dielectric constant film on said insulating barrier layer, said low dielectric constant film being a different type from the insulating barrier layer;

(c) forming a via hole that extends to said insulating barrier layer in an insulating interlayer, said insulating interlayer being composed of said insulating barrier layer and said low dielectric constant film;

(d) depositing a resin film that plugs said via hole to form a dummy plug composing said resin film in said via hole;

(e) forming a resist mask having an opening for the interconnect on said dummy plug and on said insulating interlayer; and

(f) etching said insulating interlayer via a dry etching process employing an etching mask of said resist mask to form said trench for the interconnect that is connected to said via hole, wherein, in said process for forming the dual damascene interconnect, an active hydrogen species is generated from hydrogen gas or a gaseous mixture of hydrogen gas and inert gas and is used, and an active nitrogen species is generated from nitrogen gas or a gaseous mixture of nitrogen gas and inert gas and is used.

In the above-described configuration, said active hydrogen species may be a hydrogen plasma or a hydrogen radical, and said active nitrogen species is a nitrogen plasma or a nitrogen radical.

In the above-described (a), an active hydrogen species may be applied over an anti-corrosion material on the surface of the underlying interconnect composed of a Cu-containing metallic material, which is to be coated with said insulating barrier layer, as a pre-processing before forming said insulating barrier layer, to remove said anti-corrosion material.

Said insulating barrier layer in the above-described (a) may be deposited via a chemical vapor deposition or an atomic layer deposition utilizing a reactive gas of a mixture of an organosilane gas and an active nitrogen species.

It is preferable in the above-described (d) that, after depositing said resin film, the resin film may be etched by employing an active hydrogen species to form said dummy plug that remains only in said via hole.

After the above-described (f), said resist mask and dummy plug are removed via an ashing, and continuously, said insulating barrier layer exposed on the bottom of said via hole is removed via an etching, thereby forming an electrical conductive barrier layer, which is connected to the underlying layer interconnect and functions as a Cu diffusion barrier film, within said via hole and said trench for the interconnect.

Said electrical conductive barrier layer may be preferably deposited via a chemical vapor deposition or an atomic layer deposition utilizing a reactive gas of a mixture of a metallo-organic compound and an active nitrogen species.

Further, it is preferable to remove said resist mask and dummy plug via the ashing by employing an active hydrogen species.

It is apparent that the present invention is not limited to the above embodiment, that may be modified and changed without departing from the scope and spirit of the invention.

What is claimed is:

1. A method for manufacturing an electronic device, comprising:
applying an active hydrogen species over a surface of an underlying interconnect to remove an anti-corrosion material, said underlying interconnect being formed on a substrate, having said anti-corrosion material formed on said surface thereof and containing copper;
forming an insulating barrier layer on said underlying interconnect via a chemical vapor deposition or an atomic layer deposition employing a reactive gas of a mixture of an organosilane gas and an active nitrogen species, said insulating barrier layer functioning as a copper diffusion barrier film;
forming an insulating interlayer on said insulating barrier layer, said insulating interlayer being a different type from the insulating barrier layer;
forming a first resist mask on said insulating interlayer, said first resist mask having an opening for forming a concave portion in said insulating interlayer;
etching said insulating interlayer via a dry etching process by employing said first resist mask as an etching mask to form said concave portion; and
plugging an electric conductor film in said concave portion,
wherein, said active hydrogen species is generated from hydrogen gas or a gaseous mixture of hydrogen gas and inert gas, and said active nitrogen species is generated from nitrogen gas or a gaseous mixture of nitrogen gas and inert gas, said active hydrogen species and said active nitrogen species are separately generated and used, respectively.

2. The method according to claim 1, further comprising, between said forming the insulating interlayer and said forming the first resist mask:
forming a via hole extending to said insulating barrier layer in said insulating interlayer; and
depositing a resin film that plugs said via hole to form a dummy plug composed of said resin film in said via hole,
wherein, in said forming the first resist mask, said first resist mask is formed such that said opening defines said concave portion as a trench for the interconnect formed on said dummy plug and on said insulating interlayer,
wherein, in said forming the concave portion, said trench for the interconnect connected to said via hole is formed, and
wherein, in said plugging the electric conductor film in the concave portion, said electric conductor film plugs said via hole and said trench for the interconnect to form a dual damascene interconnect.

3. The method according to claim 1, wherein said active hydrogen species is hydrogen plasma or hydrogen radical, and said active nitrogen species is nitrogen plasma or nitrogen radical.

4. The method according to claim 2, wherein said active hydrogen species is hydrogen plasma or hydrogen radical, and said active nitrogen species is nitrogen plasma or nitrogen radical.

5. The method according to claim 2, wherein, in said depositing the resin film to form the dummy plug, said resin film is etched by employing an active hydrogen species after said resin film being deposited, to form said dummy plug remaining only in said via hole.

6. The method according to claim 1, wherein, in said forming the first resist mask, said first resist mask is formed with a chemically amplified resist.

7. The method according to claim 2, wherein, in said forming the first resist mask, said first resist mask is formed with a chemically amplified resist.

8. The method according to claim 2, further comprising:
forming said via hole by employing a second resist mask having an opening for forming said via hole; and
removing said second resist mask via an ashing employing an active hydrogen species.

9. The method according to claim 1,
wherein, when an active hydrogen species and/or an active nitrogen species is employed between said applying the active hydrogen species to remove the anti-corrosion material and said plugging the electric conductor film, each of said active hydrogen species and said active nitrogen species are used separately and not used together at the same time.

10. The method according to claim 1, further comprising, after said plugging the electric conductor;
removing said electric conductor exposed at an external of said concave portion; forming an anti-corrosion material on the surface of said electric conductor; and applying an active hydrogen species over said surface of said electric conductor to remove said anti-corrosion material,
wherein, when said active hydrogen species and/or said active nitrogen species is employed between said applying the active hydrogen species to remove the anti-corrosion material formed on said surface of said underlying interconnect and applying the active hydrogen species to remove said anti-corrosion material formed on the surface of said electric conductor, each of said active hydrogen species and said active nitrogen species are used separately and not used together at the same time.

11. The method according to claim 1, further comprising,
before said applying the active hydrogen species to remove the anti-corrosion material;
plugging an interconnect material including copper within a concave portion formed in an underlying insulating interlayer formed on said substrate;
removing said interconnect material exposed at an external of said concave portion via a chemical mechanical polishing (CMP) employing an acidic slurry cleaning solution to form said underlying interconnect; and
forming said anti-corrosion material on the surface of said underlying interconnect.

12. The method according to claim 11, wherein, in said forming the underlying interconnect and in said forming the anti-corrosion material, an alkaline solution is not used.

13. The method according to claim 1, further comprising
removing said first resist mask via an ashing employing an active hydrogen species.

14. The method according to claim 2, further comprising
removing said first resist mask via an ashing employing an active hydrogen species.

15. The method according to claim 2, further comprising
removing said dummy plug via an ashing employing an active hydrogen species.

16. The method according to claim 2, further comprising, before said plugging the electric conductor film in the concave portion;
removing said first resist mask and said dummy plug via an ashing; and
subsequently, removing said insulating barrier layer exposed at the bottom of said via hole via an etching,
wherein said plugging the electric conductor film includes forming an electrical conductive barrier layer in said via hole and in said trench for the interconnect, said electrical conductive barrier layer connecting to said underlying interconnect and functioning as a copper diffusion barrier film.

17. The method according to claim 16, wherein, in said plugging the electric conductor film, said electrical conductive barrier layer is deposited via a chemical vapor deposition or an atomic layer deposition utilizing a reactive gas of a mixture of a metallo-organic compound and an active nitrogen species.
